(19) United States
(12) Patent Application Publication
(10) Pub. No.: US 2009/0181480 A1
(43) Pub. Date: Jul. 16, 2009

(54) LED heat-radiating substrate and method for making the same

(76) Inventors: Chih-Sung Chang, Hsinchu (TW); Tzer-Perng Chen, Hsinchu (TW); Pai-Hsiang Wang, Hsinchu (TW)

Correspondence Address: NORTH AMERICA INTELLECTUAL PROPERTY CORPORATION, P.O. BOX 506, MERRIFIELD, VA, 22116, US

(21) Appl. No.: 12/406,978

(22) Filed: Mar. 19, 2009

Related U.S. Application Data
(63) Continuation of application No. 10/841,639, filed on May 10, 2004.

(51) Int. Cl. H01L 21/58

(52) U.S. Cl. 438/26; 257/E21.499

(57) ABSTRACT

A method for making an LED is proposed. First a light-emitting structure is formed on a temporary substrate, and then a heat radiating substrate is formed on the light-emitting structure. Next the temporary substrate is removed. The heat radiating substrate includes a low expansion body and a high thermal conductivity body mutually connected.

### CROSS REFERENCE TO RELATED APPLICATIONS

This application is a continuation of U.S. application Ser. No. 10/841,639 filed May 10, 2004, the entirety of which is herein incorporated by reference.

### BACKGROUND OF THE INVENTION

1. Field of the Invention

The present invention relates to an LED heat-radiating substrate and a method for making the same and, more particularly, to a heat-radiating substrate applicable to an LED structure and a method for making the heat-radiating substrate.

2. Description of the Prior Art

For future applications in illumination and display, it is necessary to increase the current of light emitting diodes (LED) several or several hundred fold. The power consumption of LED thus increases several or several hundred fold. Of course, it is necessary to substantially change the conventional LED manufacturing method. In particular, the heat-radiating effect of LEDs ought to be effectively improved to enhance the light emission efficiency of LED.

Conventionally, an LED is formed by epitaxially growing a light-emitting structure on an appropriate substrate. For instance, an AlInGaP LED is formed on a GaAs substrate, while an AlInGaN LED is formed on a sapphire substrate. These substrates, however, have low thermal conductance. If the current is increased several fold, the generated heat can't be spread successfully, hence seriously affecting the light emission efficiency of the epitaxial semiconductor light emitting structure due to thermal effect. Moreover, the lifetime of the epitaxy semiconductor light emitting structure will decrease under high temperatures. Therefore, it is necessary to handle effectively the heat spread of LEDs used in high power applications.

In consideration of the above problem, a heat-radiating substrate was used in an LED. For instance, the conventional GaAs substrate is removed, and the semiconductor light emitting structure is adhered on a Si substrate. Because the Si substrate has a better thermal conductance than the GaAs substrate, the deterioration of light emission efficiency of LED can be mitigated However, the Si substrate is still a semiconductor, whose thermal conductance will drop fast along with increase of temperature. Other semiconductor substrates also have this problem. Therefore, the heat radiation of LED is still a problem not effectively solved.

In nature, metals are material having the best thermal conductance. The thermal conductance of metals like gold, silver, copper and aluminum won't drop fast along with increase in temperature. These metals, however, can't be directly used as LED substrates because their thermal expansion coefficients are much larger than those of semiconductor materials. If an LED structure is directly adhered on a metal substrate, the lattice structure thereof will be destroyed during the manufacturing procedures of the LED structure like thermal melting and baking due to thermal expansion of the metal substrate, hence damaging the LED structure. How to find an appropriate heat-radiating substrate and a method for making the same is thus an important issue to be dealt with urgently.

Accordingly, the present disclosure aims to solve the problems described above.

### SUMMARY OF THE INVENTION

An object of the present disclosure is to provide an LED heat-radiating substrate with high thermal conductance and low expansion.

To achieve the above object, the present disclosure provides an LED heat-radiating substrate whereon an LED structure is disposed to radiate heat of the LED structure. The heat-radiating substrate comprises tiny structures of low expansion bodies and high thermal conductivity bodies, which are mutually connected and confined. An LED heat-radiating substrate with high thermal conductance and low expansion is thus formed.

To achieve the above object, the present disclosure also provides an LED heat-radiating substrate whereon an LED structure is disposed to radiate heat of the LED structure. The heat-radiating substrate comprises a low expansion layer body and two high thermal conductivity layer bodies. The high thermal conductivity layer bodies are fixedly disposed at upper and lower sides of the low expansion layer body. Heat of the LED structure is conducted via the high thermal conductivity layer bodies. Moreover, the expansion of the high thermal conductivity layer bodies is limited by the low expansion layer body.

To achieve the above object, the present disclosure also provides an LED heat-radiating substrate whereon an LED structure is disposed to radiate heat of the LED structure. The heat-radiating substrate comprises slabs composed of copper-tungsten alloy or copper-molybdenum alloy.

The present disclosure also provides a method for making an LED. First a light-emitting structure is formed on a temporary substrate, and then a heat radiating substrate is formed on the light-emitting structure. Next the temporary substrate is removed. The heat radiating substrate includes a low expansion body and a high thermal conductivity body mutually connected.

The above low expansion layer body and high thermal conductivity layer bodies are mutually connected and confined.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The various objects and advantages of the present disclosure will be more readily understood from the following detailed description when read in conjunction with the appended drawing, in which:

FIG. 1 is an assembly diagram of an LED structure and a heat-radiating substrate of the present disclosure;

FIG. 2 is a diagram of a stratiform LED heat-radiating substrate of the present disclosure;

FIG. 3 is another diagram of a stratiform LED heat-radiating substrate of the present disclosure;

FIG. 4 is a diagram of a sintered LED heat-radiating substrate of the present disclosure;

FIG. 5 is another diagram of a sintered LED heat-radiating substrate of the present disclosure; and

FIG. 6 is a diagram of an LED heat-radiating substrate composed of alloys of the present disclosure.

### DETAILED DESCRIPTION

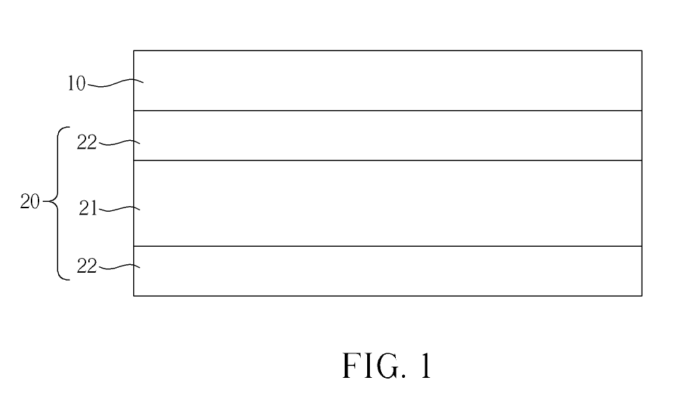

As shown in FIGS. 1 to 6, the present disclosure provides an LED heat-radiating substrate 20 whereon an LED structure 10 is disposed to radiate heat of the LED structure 10. The LED heat-radiating substrate 20 comprises low expansion bodies 21 and high thermal conductivity bodies 22, which are mutually connected and confined to form an LED heat-radiating substrate with high thermal conductance and low expansion.

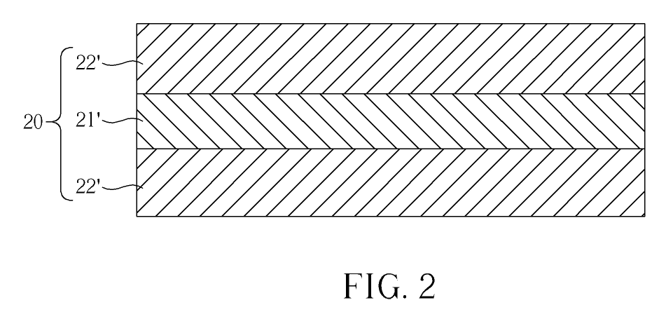

As shown in FIG. 2, the LED heat-radiating substrate 20 comprises a low expansion layer body 21′ and two high thermal conductivity layer bodies 22′. The high thermal conductivity layer bodies 22′ are fixedly connected at upper and lower sides of the low expansion layer body 21′. When the LED structure 10 is arranged on one of the high thermal conductivity layer bodies 22, heat generated by the LED structure 10 will be conducted out. Moreover, expansion of the high thermal conductivity layer bodies 22′ is limited by the low expansion layer body 21′, thereby avoiding damage to the lattice of the LED structure 10 due to expansion of the high thermal conductivity layer bodies 22′. The low expansion layer body 21′ can be a tungsten (W) slab or a molybdenum (Mo) slab. The high thermal conductivity layer bodies 22′ can be sintered bodies disposed at upper and lower sides of the low expansion layer body 21′. These layer bodies are rolled and pressed together or welded together.

The present disclosure also provides a method for making an LED heat-radiating substrate. A low expansion layer body 21′ is formed. High thermal conductivity layer bodies 22′ are then formed at upper and lower sides of the low expansion layer body 21′ to form a heat-radiating substrate with high thermal conductivity and low expansion.

The above low expansion layer body 21′ and high thermal conductivity layer bodies 22′ are mutually connected and confined.

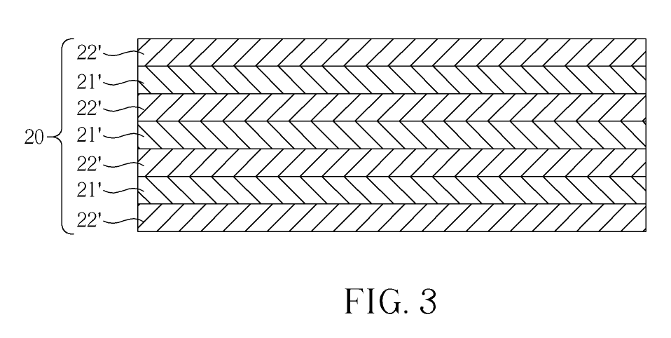

The above layer bodies can be made by means of evaporation, electroplating, casting or electroforming. Reference is made to FIG. 3. The low expansion layer bodies 21′ can further be formed at outer sides of the high thermal conductivity layer bodies 22′, and the high thermal conductivity layer bodies 22′ can further be formed at outer sides of the low expansion layer bodies 21′, thereby forming a multi-layer heat-radiating substrate 20.

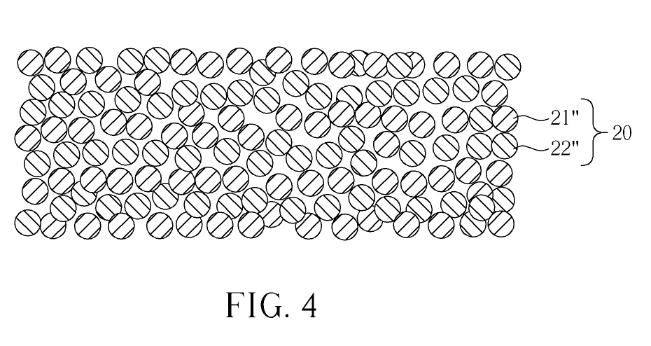

Reference is made to FIG. 4. The LED heat-radiating substrate 20 comprises tiny structures of the low expansion bodies 21 and the high thermal conductivity bodies 22, which are mutually connected and confined to form the LED heat-radiating substrate 20 with high thermal conductance and low expansion. The tiny structures of the low expansion bodies 21 are low expansion powder bodies 21″ such as tungsten (W) powder bodies, molybdenum (Mo) powder bodies, diamond powder bodies or silicon carbide (SiC) powder bodies. The tiny structures of the high thermal conductivity bodies 22 are high thermal conductivity powder bodies 22″ such as copper (Cu) powder bodies. The low expansion powder bodies 21″ and the high thermal conductivity powder bodies 22″ are sintered to form a sintered heat-radiating substrate 20.

The present disclosure also provides a method for making the sintered heat-radiating substrate 20. Thermal conductivity powder bodies 22″ and low expansion powder bodies 21″ are provided. The high thermal conductivity powder bodies 22″ and the low expansion powder bodies 21″ are mixed. The mixed high thermal conductivity powder bodies 22″ and low expansion powder bodies 21″ are pressed to form a solid body. The pressed solid body is then sintered to form a heat-radiating substrate with high thermal conductivity and low expansion.

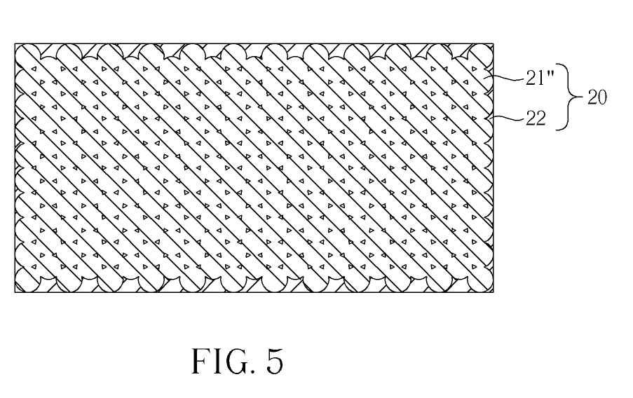

Reference is made to FIG. 5. The present disclosure also provides another method for making the heat-radiating substrate 20. The low expansion powder bodies 21″ is provided. The low expansion powder bodies 21″ are pressed to form a solid body. The pressed solid body is sintered to form a sintered body having holes. The holes of the sintered body are permeated with a high thermal conductivity liquid 22. The high thermal conductivity liquid 22 in the sintered body is then solidified to form a heat-radiating substrate with high thermal conductivity and low expansion.

The high thermal conductivity liquid 22 is liquid metal like liquid copper (Cu).

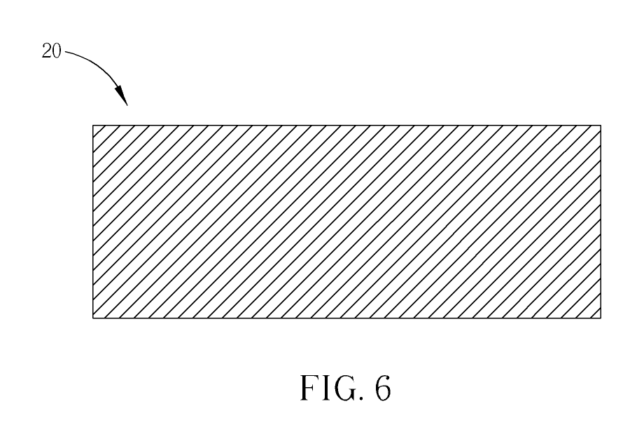

Reference is made to FIG. 6. The LED heat-radiating substrate 20 can be made of copper-tungsten (Cu—W) alloy or copper-molybdenum (Cu—Mo) alloy. Copper-tungsten (Cu—W) alloy powder bodies or copper-molybdenum (Cu—Mo) alloy powder bodies can be sintered to form a heat-radiating substrate 20 with high thermal conductance and low expansion.

To sum up, the present disclosure proposes an LED heat-radiating substrate to accomplish the effects of high thermal conductance and low expansion. When an LED structure is arranged on the heat-radiating substrate, it is not destroyed due to heat expansion and cold shrinkage of the heat-radiating substrate.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for making an LED, comprising the steps of:
forming a light-emitting structure on a temporary substrate;
forming a heat radiating substrate on the light-emitting structure; and
removing the temporary substrate;
characterized in that the heat radiating substrate comprises a low expansion body and a high thermal conductivity body mutually connected.

2. The method according to claim 1, wherein the low expansion body or the high thermal conductivity body is in the form of layer body.

3. The method according to claim 2, wherein the low expansion body or the high thermal conductivity body is in the form of slab body.

4. The method according to claim 1, wherein the low expansion body or the high thermal conductivity body is in the form of powder body.

5. The method according to claim 1, wherein the bodies are rolled and pressed together.

6. The method according to claim 1, wherein the bodies are welded together.

7. The method according to claim 1, wherein the bodies are made by means of evaporation.

8. The method according to claim 1, wherein the bodies are made by means of electroplating.

9. The method according to claim 1, wherein the bodies are made by means of casting.

10. The method according to claim 1, wherein the bodies are made by means of electroforming.

11. The method according to claim 1, wherein the low expansion body comprises tungsten, molybdenum, diamond, or silicon carbide.

12. The method according to claim 1, wherein the high thermal conductivity body comprises copper.

13. The method according to claim 1, wherein the step of forming the heat radiating substrate further comprises the steps of
forming a low expansion layer; and
forming high thermal conductivity layers on upper and lower sides of the low expansion layer.

14. The method according to claim 1, wherein the step of forming the heat radiating substrate further comprises the steps of
forming a high thermal conductivity layer; and
forming low expansion layers on upper and lower sides of the high thermal conductivity layer.
